(19) United States
(12) Patent Application Publication
(10) Pub. No.: US 2026/0358695 A1
(43) Pub. Date: Nov. 12, 2026

(54) SUPER BINARY MASK WITH ESD PROTECTION

(71) Applicant: Taiwan Semiconductor Manufacturing Co., Ltd., Hsinchu (TW)

(72) Inventors: Jen-Hsi CHIU, Hsinchu (TW); Po-Ming HSU, Hsinchu (TW); Yi-Chun CHOU, Hsinchu (TW); Jong-Yuh CHANG, Hsinchu (TW)

(73) Assignee: Taiwan Semiconductor Manufacturing Co., Ltd., Hsinchu (TW)

(21) Appl. No.: 19/205,583

(22) Filed: May 12, 2025

(51) Int. Cl. G03F 1/40; G03F 7/00; G03F 7/09

(52) U.S. Cl. CPC G03F 1/40; G03F 7/091; G03F 7/70066; G03F 7/70091

(57) ABSTRACT

A photolithography reticle includes a substrate including a back surface and a front surface. The substrate is transparent to a wavelength of photolithography light of a photolithography system in which the reticle is to be deployed. The reticle includes an absorption structure on the front surface of the quartz. The absorption structure includes an absorption layer having a material that is opaque to the photolithography light. The reticle includes a trench in the absorption structure exposing the front surface of the substrate. The reticle includes a dielectric protection layer on a top surface of the absorption structure configured to inhibit electrostatic discharge during photolithography processes.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

Photolithography systems play an integral role in semiconductor processing. The scaling down of integrated circuit features is limited, in part, by the features of the photolithography systems. The photolithography system utilizes a photolithography mask or reticle. During a photolithography process, photolithography light is passed through or reflected from the reticle so that the photolithography light will carry a pattern of the reticle to a wafer. However, as the patterns in photolithography reticle become increasingly more dense, various problems can arise.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventor’s approach to the particular problem, which, in and of itself, may also be inventive.

### BRIEF DESCRIPTION OF THE DRAWINGS

FIG. 1 is a block diagram of a photolithography system, in accordance with some embodiments.

FIG. 2-6 are cross-sectional views and top views of a photolithography reticle at various stages of processing, in accordance with some embodiments.

FIG. 7 is an enlarged cross-sectional view of a portion of a reticle during a reticle repair process, in accordance with some embodiments.

FIG. 8A is an illustration of a reticle layout, in accordance with some embodiments.

FIG. 8B is an illustration of a wafer layout associated with the reticle layout of FIG. 8A, in accordance with some embodiments.

FIG. 9A is an illustration of a reticle layout, in accordance with some embodiments.

FIG. 9B is an illustration of a wafer layout associated with the reticle layout of FIG. 9A, in accordance with some embodiments.

FIG. 10A is an illustration of a reticle layout, in accordance with some embodiments.

FIG. 10B is an illustration of a reticle layout, in accordance with some embodiments.

FIG. 11 is a flow diagram of a method for utilizing a photolithography reticle, in accordance with some embodiments.

FIG. 12 is a flow diagram of a method for repairing a photolithography reticle, in accordance with some embodiments.

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “some embodiments” or “an embodiment” means that a particular feature, structure or characteristic described in connection with the embodiment is included in at least some embodiments. Thus, the appearances of the phrases “in some embodiments” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

As used in this specification, “light” generally refers to electromagnetic radiation of any wavelength, except where a particular band or wavelength is specified.

As used in this specification, “reticle” corresponds to a photolithography mask or photomask.

Embodiments of the present disclosure provide a photolithography reticle that avoids at least some of the drawbacks of previous photolithography reticles. The photolithography reticle includes an electrostatic discharge (ESD) protection layer on a transmission face of the reticle. The reticle includes a transparent substrate and an absorption layer on the substrate. The absorption layer is patterned with a series of trenches that expose the transparent substrate. The pattern of the trenches corresponds to the pattern of the photolithography reticle. The ESD protection layer is positioned on end portions of the absorption layer, or on end portions of a layer that is positioned on the absorption layer and patterned in the same manner. During use of the reticle, photolithography light irradiates the back of the transparent substrate and passes through the trenches. The photolithography light leaving the transmission face carries the pattern of the trenches. During this irradiation, charged particles can build up on the ends of the columns of absorption material. The ESD protection layer prevents electrostatic discharge from the ends of the columns.

Prevention of electrostatic discharge at the transmission face of the reticle helps to ensure that photolithography processes properly pattern the wafers. ESD events during a photolithography process can result in distortion of the pattern of the photolithography light. ESD events can also damage the reticle itself. The ESD protection layer helps ensure that such distortions and reticle damage do not happen. This results in better functioning integrated circuits and fewer scrapped wafers. Furthermore, this prevents destruction of reticles and corresponding expensive delays in performing photolithography processes when a damaged reticle needs to be replaced or repaired.

Embodiments of the present disclosure also enable effective repair of damaged reticles. During use of a photolithography reticle, sometimes there is a buildup of the absorption material on the bottoms of the trenches. An e-beam lithography tool is utilized to clear off unwanted absorption material from the bottoms of the trenches. The ESD protection layer is resistant to damage from the electron-beam. The ESD protection layer helps ensure that the columns of absorption material are not damaged by the e-beam lithography tool during repair of the reticle.

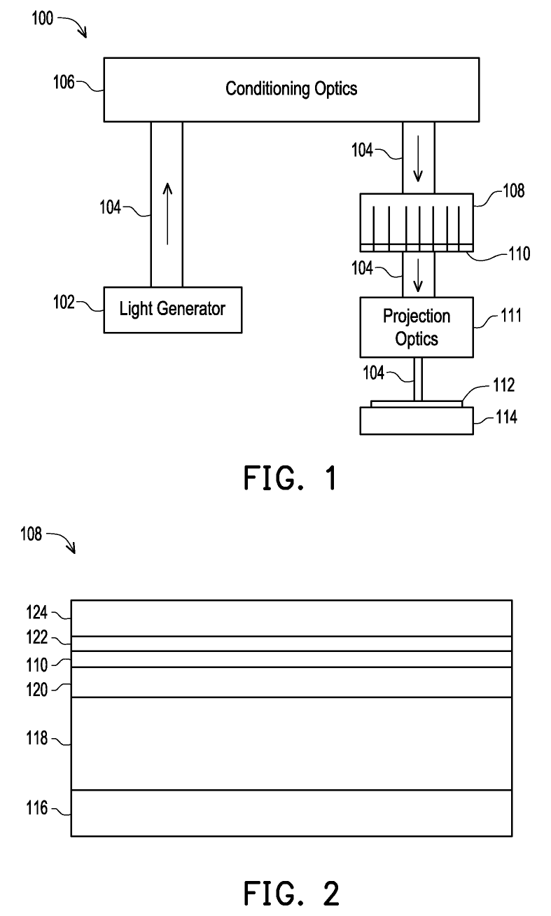

FIG. 1 is an illustration of photolithography system 100, in accordance with some embodiments. The photolithography system 100 generates photolithography light to pattern a semiconductor wafer. As will be set forth in more detail below, the components of the photolithography system help to ensure that the photolithography processes are properly performed.

In some embodiments, the photolithography system 100 is a deep ultraviolet (DUV) photolithography system. While the description of FIG. 1 focuses primarily on a DUV photolithography system, other types of photolithography systems can be utilized without departing from the scope of the present disclosure. For example, in some embodiments, the photolithography system 100 is an EUV photolithography system.

The photolithography system 100 includes a light generator 102, conditioning optics 106, a reticle 108, projection optics 111, and a wafer stage 114 configured to hold a wafer 112. The light generator 102 generates photolithography light 104 and provides the photolithography light 104 to conditioning optics 106. The conditioning optics 106 conditions the photolithography light 104 and passes the photolithography light 104 to a reticle 108 including a mask pattern. The photolithography light 104 passes through the reticle 108. After the photolithography light 104 passes through the reticle 108, the photolithography light 104 carries the pattern of the reticle 108. The photolithography light 104 passes from the reticle 108 to projection optics 111. The projection optics 111 focus the photolithography light 104 onto the wafer 112. The photolithography light 104 patterns a layer on the wafer 112 in accordance with a pattern of the reticle 108. Each of these processes and components is described in more detail below.

In some embodiments, the light generator 102 generates photolithography light 104. In some embodiments, the light generator 102 generates photolithography light 104 with a wavelength of about 193 nm. In some embodiments, the light generator 102 includes an excimer laser that assists in generating the photolithography light 104. Other wavelengths of light can be utilized without departing from the scope of the present disclosure.

The conditioning optics 106 include a plurality of optical devices that condition the photolithography light 104 and pass the photolithography light 104 toward the reticle 108. In some embodiments, the conditioning optics 106 include one or more lenses that focus and direct the photolithography light 104 along a path toward the reticle 108. In some embodiments, the conditioning optics include one or more mirrors that reflect the photolithography light 104 along a path toward the reticle 108. In some embodiments, the conditioning optics 106 include one or more diffusers that defuse an intensity or phase of the photolithography light 104. In some embodiments, the conditioning optics 106 are part of a photolithography scanner. The conditioning optics 106 can include various other components or architectures without departing from the scope of the present disclosure.

In some embodiments, the reticle 108 is a transmission type reticle. In particular, the reticle 108 includes a transparent substrate with a back surface that faces the conditioning optics. The back surface of the transparent substrate is an incidence face of the reticle 108. This is because the photolithography light 104 is incident on the back surface of the transparent substrate. The transparent substrate includes a material that is transparent to the wavelength of the photolithography light 104. In an example in which the photolithography light 104 has a wavelength of 193 nm, the transparent substrate is of a material that is transparent to light having a wavelength of 193 nm. In some embodiments, the transparent substrate includes quartz, though other materials can be utilized without departing from the scope of the present disclosure.

The reticle 108 includes an absorption layer on the front face of the transparent substrate. The front face is opposite the incidence face. The absorption material includes a material that is configured to absorb the photolithography light 104. In an example in which the photolithography light 104 has a wavelength of 193 nm, the absorption layer includes a material that absorbs light having a wavelength of 193 nm. In some embodiments, the absorption material includes MoSi, though other materials can be utilized without departing from the scope of the present disclosure. The absorption material is patterned with a series of trenches that expose the transparent substrate. The pattern of the trenches corresponds to the pattern of the photolithography reticle 108.

During the photolithography process, the photolithography light 104 is incident on the back face of the reticle 108. The photolithography light 104 passes through the transparent substrate of the reticle 108. The portion of the photolithography light that passes from the transparent substrate to the absorption material is absorbed by the absorption material. The portion of the photolithography light 104 that passes from the transparent substrate to the trenches continues on past the reticle 108. The face of the reticle 108 that is opposite the incidence face is a transmission face. As can be seen in FIG. 1, the reticle 108 includes an ESD protection layer 110 positioned that the transmission face of the reticle 108. Further details regarding the ESD protection layer 110 are provided below.

The photolithography light 104 passes from the transmission face toward the projection optics 111. In some embodiments, the projection optics 111 includes refractive optics, reflective optics, or combination of refractive and reflective optics. The projection optics 111 may include a magnification less than 1, thereby reducing the patterned image included in the photolithography light 104 reflected from the reticle 108. The projection optics 111 directs the photolithography light 104 onto the wafer 112, for example, a semiconductor wafer.

In some embodiments, the patterned absorption layer of the reticle 108 includes a pattern of columns or walls of absorption material. The columns or walls of the absorption material are defined by the pattern of trenches. In some embodiments, the ESD protection layer 110 is formed on the top surface of the columns or walls of absorption material. The ESD protection layer 110 may be termed a dielectric protection layer.

In some embodiments, an anti-reflection layer is positioned on the absorption layer. The anti-reflection layer corresponds to an extension of the columns or walls of the absorption material. The anti-reflection layer has the same pattern as the absorption layer. In these cases, the ESD protection layer 110 is formed on the top surface of the antireflective layer. In some embodiments, the antireflective layer includes a material that inhibits reflection of the photolithography light 104. In some embodiments, the antireflective layer includes a plurality of layers that collectively inhibit reflection of the photolithography light 104.

During the photolithography process, charged particles may accumulate on the various surfaces of the reticle 108. Most particularly, the charged particles may accumulate at the ends of the absorption structures of the absorption layer or the antireflective layer at the transmission face of the reticle. In the absence of the ESD protection layer 110, it is possible that the accumulation of charges at the ends of the absorption structures can result in ESD events in which arcing or other types of electrostatic discharge may occur. These ESD events are potentially very harmful to the reticle and to the photolithography process.

In some embodiments, an ESD event can damage the reticle. The arcing or other ESD event can result in material being ejected from or breaking away from the walls/columns of the patterned reticle. If the damage is great enough, the reticle may need to be repaired or discarded. In either case, photolithography processes are stopped until the reticle is replaced or repaired. This is highly expensive as a long duration of time may elapse during which photolithography processes cannot be performed with the photolithography system 100. In cases in which the reticle is scrapped, replacement of the reticle can be very expensive.

In some embodiments, an ESD event distorts the pattern of the photolithography light as the photolithography light leaves the reticle. This can result in failure to properly impart the pattern of the reticle to a photoresist layer on the wafer. This further results in faulty patterning of the layers of the wafer below the photoresist layer. This can result in poorly functioning integrated circuits, or even scrapped wafers.

The ESD protection layer 110 in accordance with principles of the present disclosure reduces or illuminates ESD events at the transmission face of the reticle 108. The ESD protection layer 110 includes a material with a much higher resistivity than the material of the absorption layer or the antireflective layer. In some embodiments, the material of the ESD protection layer 110 has a sheet resistance that is between 1000 and 10000 times greater than the sheet resistance of the material of the antireflection layer, or the material of the anti-absorption layer. The result is a reduction in the accumulation of charged particles during photolithography processes. This further prevents ESD events at the transmission face of the reticle 108.

In some embodiments, the ESD protection layer 110 includes a dielectric material. In some embodiments, the ESD protection layer 110 includes silicon oxynitride, silicon nitride, silicon oxide, aluminum oxide, yttrium oxide, titanium oxide, zirconium oxide. More particularly, in some embodiments, the dielectric material includes SiON, SiO2, Si3N4, Al2O3, Y2O3, TiO2, or ZrO2. In some embodiments, the ESD protection layer 110 has a thickness between 5 nm and 15 nm. Other materials and thicknesses can be utilized for the ESD protection layer 110 without departing from the scope of the present disclosure.

During use of the reticle 108, it is possible that material from the absorption layer will accumulate on the surface of the transparent substrate at the bottom of a trench of the reticle 108. Such accumulations can result in a portion of the trench effectively becoming opaque. This will distort the pattern of the photolithography light 104 and can result in scrapped wafers or poorly functioning integrated circuits.

The ESD protection layer 110 can help protect the reticle 108 during a repair process of the reticle 108. During the repair process, an e-beam lithography tool is utilized to clear off unwanted absorption material from the bottoms of the trenches. The e-beam lithography tool outputs an electron-beam into the trenches to clear off absorption material from the bottom of the trenches. In the absence of the ESD protection layer 110, it is possible that this electron-beam will damage the tops of the walls/columns of absorptive material/antireflection material. Beneficially, the presence of the ESD protection layer protects the absorption structures. The material of the ESD protection layer 110 is highly resistant to being damaged by the electron-beam. Accordingly, portions of the electron-beam that impact the absorption structures will not damage the walls/columns because the walls/columns are capped with the ESD protection layer 110.

FIGS. 2-6 are cross-sectional and top views of a photolithography reticle 108 at various stages of processing, in accordance with some embodiments. The photolithography reticle 108 of FIGS. 2-6 is one example of a photolithography reticle 108 of FIG. 1. At the stage of processing shown in FIG. 2, the reticle 108 is a mask blank (unpatterned).

In some embodiments, the reticle 108 is a super binary intensity mask (SBIM). In some embodiments, the SBIM mask is an Opaque MoSi on glass (OMOG) reticle.

The photolithography reticle 108 includes a transparent substrate 116. In the view of FIG. 2, the bottom surface of the transparent substrate 116 is the incident surface of the photolithography reticle 108. In other words, during a photolithography process utilizing the reticle 108 after processing of the reticle 108 is complete, the photolithography light is incident on the back surface of the transparent substrate 116.

In some embodiments, the transparent substrate 116 has a thickness between 6.0 mm and 6.7 mm In an example in which the photolithography light 104 has a wavelength of 193 nm, the transparent substrate is of a material that is transparent to light having a wavelength of 193 nm. In some embodiments, the transparent substrate includes quartz. Other materials and thicknesses can be utilized without departing from the scope of the present disclosure.

The reticle 108 includes an absorption layer 118 on the front face or top surface of the transparent substrate 116. The absorption material includes a material that is configured to absorb the photolithography light 104. In an example in which the photolithography light 104 has a wavelength of 193 nm, the absorption layer includes a material that absorbs light having a wavelength of 193 nm. In some embodiments, the absorption material includes MoSi. In some embodiments, the absorption layer 118 has a thickness between 40 nm and 50 nm. Other materials can be utilized without departing from the scope of the present disclosure.

In some embodiments, the reticle 108 includes an antireflection layer 120 on the absorption layer 118. The antireflection layer 120 helps to prevent or reduce reflection of photolithography light within the reticle 108. In some embodiments, the antireflection layer 120 includes MoSi. In some embodiments, the antireflection layer 120 has a thickness between 10 nm and 20 nm. Other materials and thicknesses can be utilized without departing from the scope of the present disclosure. In some embodiments, the antireflection layer 120 has a sheet resistance between 3E4 ohms/square and 4E4 ohms/square. In some embodiments, the ESD protection layer 110 has a sheet resistance between 6E7 ohms/square and 7E7 ohms/square. In some embodiments, the absorption layer 118 includes an oxide of silicon molybdenum, while the antireflective layer 120 includes MoSi.

While FIGS. 2-6 illustrate the presence of an antireflection layer 120 on the absorption layer 118, in some embodiments the antireflection layer 120 is not present. Instead, the ESD protection layer 110 is formed directly on the top surface of the absorption layer 118.

In ESD protection layer 110 is formed on the antireflective layer 120, in accordance with some embodiments. In some embodiments, the antireflection layer 120 is not present and the ESD protection layer 110 is formed directly on top of the absorption layer 118.

In some embodiments, the ESD protection layer 110 includes a dielectric material. In some embodiments, the ESD protection layer 110 includes silicon oxynitride, silicon nitride, silicon oxide, aluminum oxide, yttrium oxide, titanium oxide, zirconium oxide. In some embodiments, the ESD protection layer 110 has a thickness between 5 nm and 15 nm. Other materials and thicknesses can be utilized for the ESD protection layer 110 without departing from the scope of the present disclosure.

In some embodiments, the reticle 108 includes a hard mask layer 122 formed on the ESD protection layer 110. As will be set forth in more detail below, the hard mask layer 122 will be patterned in accordance with a photolithography process in order to form a pattern of trenches in the reticle 108. In some embodiments, the hard mask layer 122 includes chromium. In some embodiments, the hard mask layer 122 has a thickness between 2 nm and 5 nm. Other thicknesses and materials can be utilized for the hard mask layer 122 without departing from the scope of the present disclosure.

In some embodiments, the reticle 108 includes a layer of photoresist 124 formed on the hard mask layer 122. The layer of photoresist 124 includes a material that changes composition upon being exposed to the photolithography light 104. The layer of photoresist 124 has a thickness between 70 nm and 90 nm. Other thicknesses can be utilized without departing from the scope of the present disclosure.

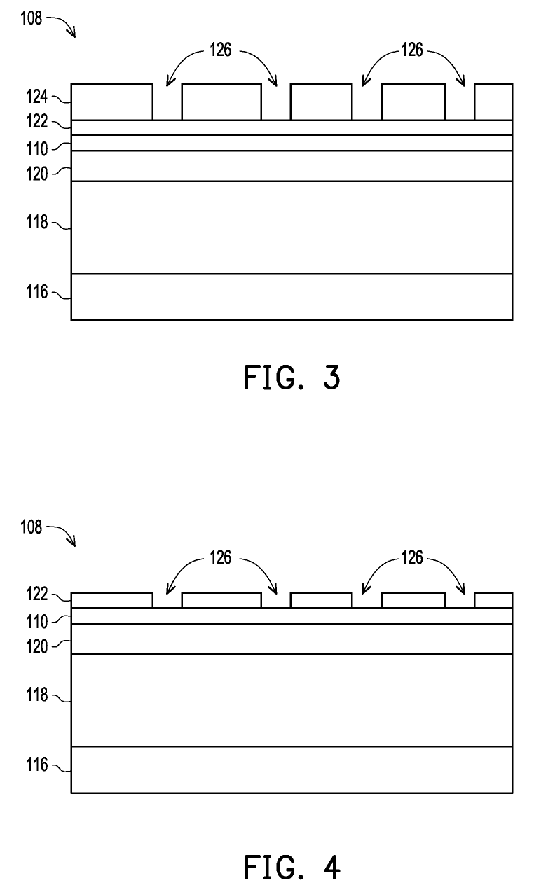

In FIG. 3, the layer of photoresist 124 has been exposed to photolithography light 104 and developed, in accordance with some embodiments. The photolithography light 104 includes a pattern that forms trenches 126 in the layer of photoresist 124. The trenches 126 have the pattern of the trenches that will be formed in the absorption layer 118. The layer of photoresist 124 has been developed in FIG. 3.

In FIG. 4, an etching process has been performed in the presence of the layer of photoresist 124, in accordance with some embodiments. The etching process extends the trenches 126 through the hard mask layer 122 to expose the ESD protection layer 110. The etching process can include a dry etch that etches in the downward direction and selectively etches the material of the hard mask layer 122 with respect to the material of the ESD protection layer 110.

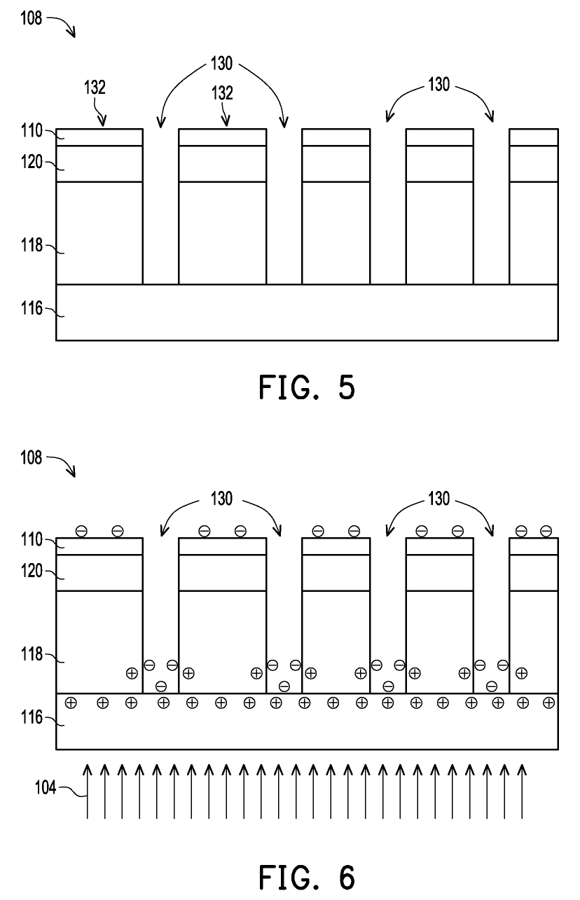

In FIG. 5, an etching process has been performed, in accordance with some embodiments. The etching process forms trenches 130 in the ESD protection layer 110, the antireflective layer 120 and the absorption layer 118. The etching process forms the trenches 130 in the pattern of the hard mask layer 122 as shown in FIG. 4. The trenches 130 extends through the ESD protection layer 110, the antireflective layer 120, and the absorption layer 118 to expose the top surface of the transparent substrate 116. The etching process can include a single etching step to etch through all of the layers or multiple etching steps that each etch through one of the layers of the reticle 108.

In some embodiments, the patterning process forms absorption structures 132 of the absorption layer 118 and the antireflection layer 120. The absorption structures 132 are defined by the trenches 130 and are based on the pattern to be imparted to wafers in photolithography processes utilizing the reticle 108. The absorption structures are walls/columns of the absorption layer 118 and the antireflection layer 120. The ESD protection layer 110 is positioned on top of the absorption structures 132. The ESD protection layer 110 is considered part of the absorption structures 132, in accordance with some embodiments.

In FIG. 5, the reticle 108 includes the pattern that will be utilized to pattern semiconductor wafers, in accordance with some embodiments. Accordingly, the reticle 108 is used in photolithography processes. In some embodiments, the reticle 108 is a binary mask. In some embodiments, the reticle 108 is a super binary mask. Other types of reticles can be utilized without departing from the scope of the present disclosure.

FIG. 6 illustrates the reticle 108 of FIG. 5 during a photolithography process, in accordance with some embodiments. The reticle 108 of FIG. 6 is one example of the reticle 108 of FIG. 1 implemented in the photolithography system 100 of FIG. 1.

In FIG. 6, photolithography light 104 is incident on the back surface of the transparent substrate 116. The portion of the photolithography light 104 that passes from the transparent substrate 116 to the absorption layer 118 is absorbed by the material of the absorption layer 118. The portion of the photolithography light 104 that passes from the transparent substrate 116 to the trenches 130 continues through the trenches to the transmission face of the reticle 108, to the projection optics 111, and onto the wafer 112.

As can be seen in FIG. 6, positively charged particles accumulate at the top surface of the transparent substrate 116. Positively particles also accumulate within the absorption material adjacent to the trenches 130. Negatively charged particles accumulate in the lower portions of the trenches 130. As can be seen in FIG. 6, negatively charged particles accumulate at the top surface of the ESD protection layer 110.

As set forth previously, the ESD protection layer 110 includes a material with a much higher resistivity than the material of the absorption layer 118 or the antireflective layer 120. The result is a reduction in the accumulation of negatively charged particles during photolithography processes. This further prevents ESD events at the transmission face of the reticle 108. In some embodiments, the material of the ESD protection layer 110 has a sheet resistance that is between 1000 and 10000 times greater than the sheet resistance of the material of the antireflection layer, or the material of the anti-absorption layer.

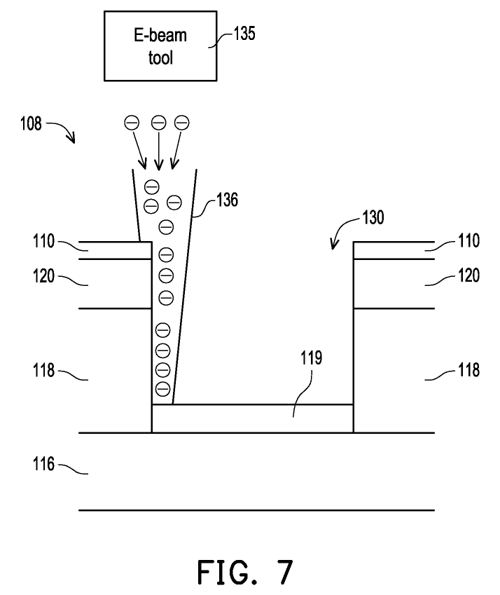

FIG. 7 is a cross-sectional view of a portion of a reticle 108, in accordance with some embodiments. The reticle 108 includes the transparent substrate 116, the absorption layer 118, the antireflective layer 120, and the ESD protection layer 110, as described previously. FIG. 7 illustrates a single trench 130 in the absorption layer 118. In the view of FIG. 7, an accumulation of opaque material 119 is present in the bottom of the trench 130 on the top surface of the transparent substrate 116. This corresponds to a defect in the reticle 108. It would be beneficial to repair the defect by removing the opaque material 119. The opaque material 119 can correspond to a portion of the absorption layer 118 that was not entirely removed during forming of the mask 108. Alternatively, the opaque material 119 can correspond to a portion of the absorption layer 118 that was removed from the absorption layer 118 by damage or in some other manner. Accordingly, in some embodiments, the opaque material 119 is a same material as the absorption layer 118.

In FIG. 7, an e-beam lithography tool 135 is utilized to repair the reticle 108. The e-beam lithography tool 135 repairs the reticle 108 by projecting an electron-beam 136 onto the bottom of the trench 130. Though not shown in FIG. 7, a reaction gas is also introduced to assist the electron-beam in removing the opaque material 119 from the bottom of the trench 130. Accordingly, the e-beam lithography tool 135 utilizes the electron-beam 136 to remove the opaque material 119 from the bottom of the trench 130. Although the material 119 is described as absorption material, other types of debris, or material accumulation can be removed/repaired at the bottom of the trenches 130 with the electron-beam 136. In some embodiments, the reaction gas includes XeF_{2.}

As can be seen in FIG. 7, the electron-beam 136 has a conical profile, in accordance with some embodiments. A portion of the electron-beam 136 impacts the ESD protection layer 110. However, the ESD protection layer 110 is of a composition that is resistant to being damaged or removed by the electron-beam 136 and the reaction gas. Accordingly, the antireflection layer 120 and the absorption layer 118 are protected by the ESD protection layer 110 from being damaged by the electron-beam 136 during the repair process. Accordingly, the ESD protection layer 110 beneficially helps to ensure that repair processes can be performed without damaging the reticle 108.

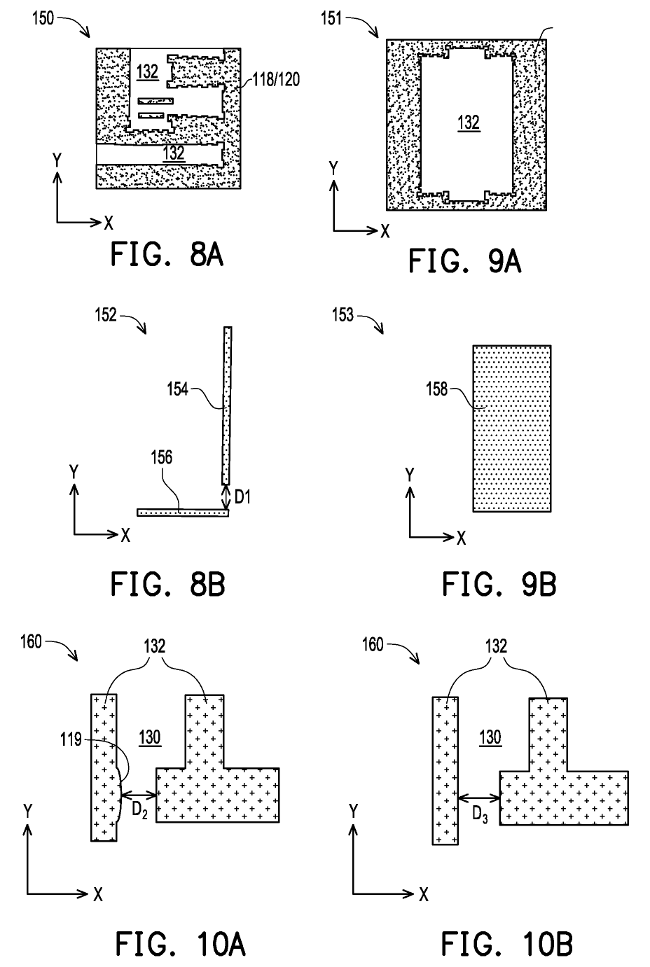

FIG. 8A is an illustration of a reticle pattern 150, in accordance with some embodiments. The reticle pattern 150 corresponds to a top view of a portion of a reticle 108, in accordance with some embodiments. FIG. 8A illustrates trenches 130 and absorption structures 132. In some embodiments, the reticle pattern corresponds to an ESD monitor pattern. In particular, the pattern are the layout on the reticle 108 that monitors ESD. The uneven pattern increases the possibility of ESD so that ESD can be monitored.

FIG. 8B illustrates a wafer layout 152 associated with the reticle pattern 150 of FIG. 8A, in accordance with some embodiments. The wafer layout 152 includes a first line 154 extending in the Y direction, and a second line 156 extending in the X direction. The line 154 and the line 156 are separated by a gap with a dimension D1 in the Y direction. D1 is between 70 nm and 110 nm. The length of the line 154 in the Y direction is between 2500 µm and 3500 µm. The width of the line 154 in the X direction is between 0.25 µm and 0.3 µm. The length of the line 156 in the X direction is between 500 µm and 1500 µm. The width of the line 156 in the Y direction is between 0.1 µm and 0.2 µm. Other dimensions can be utilized without departing from the scope of the present disclosure.

FIG. 9A is an illustration of a reticle pattern 151, in accordance with some embodiments. The reticle pattern 151 corresponds to a top view of a portion of a reticle 108, in accordance with some embodiments. FIG. 9A illustrates trenches 130 and absorption structures 132. In some embodiments, the reticle pattern 151 corresponds to an ESD monitor pattern.

FIG. 9B illustrates a wafer layout 153 associated with the reticle pattern 151 of FIG. 9A, in accordance with some embodiments. The wafer layout 153 includes a large area line 158 extending in the Y direction. The length of the line 158 in the Y direction is between 500 µm and 1500 µm. The width of the line 158 in the X direction is between 15 µm and 25 µm. Other dimensions can be utilized without departing from the scope of the present disclosure.

FIG. 10A is a portion of developed photoresist patterned in accordance with a damaged reticle, in accordance with some embodiments. The developed photoresist includes trenches based on the trenches 130 and absorption structures 132 of a reticle 160. In some embodiments, there is a defect in which a portion of the trench 130 is covered in an opaque material 119 in an undesirable manner. This effectively creates a reduced separation dimension D2. The damage to the reticle can be caused by ESD resulting in a defect in the patterned photoresist that shrinks the critical dimension by 20% or more.

FIG. 10B is a portion of developed photoresist patterned with an undamaged (or repaired) reticle 160, in accordance with some embodiments. The patterned photoresist of FIG. 10B is different than the patterned photoresist of FIG. 10A in that the opaque material 119 is not present in the reticle that patterns the photoresist and the separation dimension is D3. In some embodiments, the absence of the opaque material 119 is a result of a successful repair procedure as described in relation to FIG. 7. In some embodiments, the absence of the opaque material 119 is a result of the ESD protection layer 110 pending present during patterning of the reticle layout 160, such that the opaque material 119 does not accumulate. In some embodiments, D2 is 20% smaller than D3. This corresponds to a 20% shrinkage of the critical dimension.

The ESD monitor pattern is one feature of principles of the present disclosure. ESD is prone to happen on certain specific patterns after a lot of scanner exposure. Some embodiments include some specific patterns to monitor the ESD status on the mask to understand the health of the reticle.

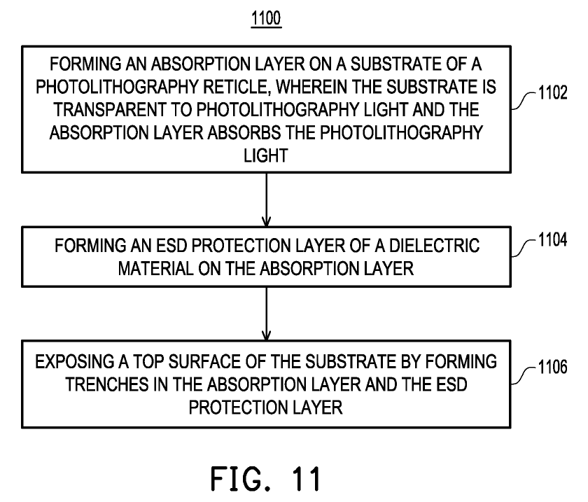

FIG. 11 is a flow diagram of a method 1100, in accordance with some embodiments. The method 1100 can utilize processes, structures, and systems described in relation to FIGS. 1-10B. At 1102, the method 1100 includes forming an absorption layer on a substrate of a photolithography reticle, wherein the substrate is transparent to photolithography light and the absorption layer absorbs the photolithography light. One example of a photolithography reticle is the photolithography reticle 108 of FIG. 2. One example of an absorption layer is the absorption layer 118 of FIG. 2. One example of a substrate is the substrate 116 of FIG. 2. At 1104, the method 1100 includes forming an ESD protection layer of a dielectric material on the absorption layer. One example of an ESD protection layer is the ESD protection layer 110 of FIG. 2. At 1106, the method 1100 includes exposing a top surface of the substrate by forming trenches in the absorption layer and the ESD protection layer. One example of trenches are the trenches 130 of FIG. 5.

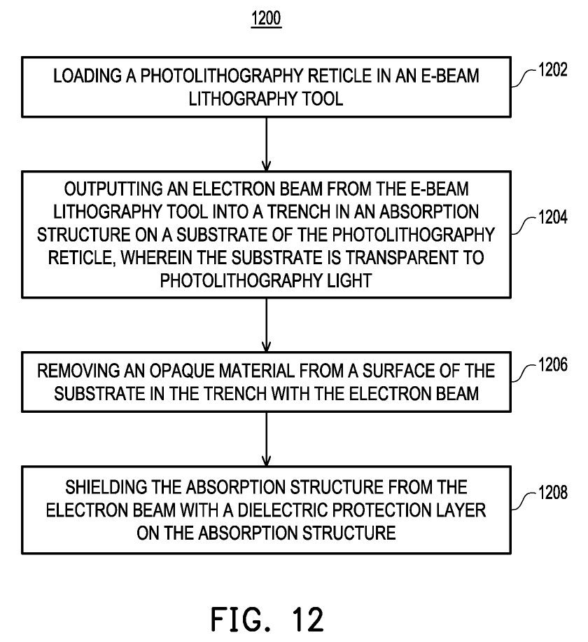

FIG. 12 is a flow diagram of a method 1200, in accordance with some embodiments. The method 1200 can utilize processes, structures, and systems described in relation to FIGS. 1-10B. At 1202, the method 1200 includes loading a photolithography reticle in an e-beam lithography tool. One example of a photolithography reticle is the photolithography reticle 108 of FIG. 7. One example of an e-beam lithography tool is the e-beam lithography tool 135 of FIG. 7. At 1204, the method 1200 includes outputting an electron beam from the e-beam lithography tool into a trench in an absorption structure on a substrate of the photolithography reticle, wherein the substrate is transparent to photolithography light. One example of an electron-beam is the electron-beam 136 of FIG. 7. One example of a substrate is the substrate 116 of FIG. 7. One example of an absorption structure is the absorption structure 132 of FIG. 7. One example of a trench is the trench 130 of FIG. 7. At 1206, the method 1200 includes removing an opaque material from a surface of the substrate in the trench with the electron beam. One example of an opaque material is the opaque material 119 of FIG. 7. At 1208, the method 1200 includes shielding the absorption structure from the electron beam with a dielectric protection layer on the absorption structure. One example of a dielectric protection layer is the dielectric protection layer 110 of FIG. 7.

Embodiments of the present disclosure provide a photolithography reticle that avoids at least some of the drawbacks of previous photolithography reticles. The photolithography reticle includes an electrostatic discharge (ESD) protection layer on a transmission face of the reticle. The reticle includes a transparent substrate and an absorption layer on the substrate. The absorption layer is patterned with a series of trenches that expose the transparent substrate. The pattern of the trenches corresponds to the pattern of the photolithography reticle. The ESD protection layer is positioned on end portions of the absorption layer, or on end portions of a layer that is positioned on the absorption layer and patterned in the same manner. During use of the reticle, photolithography light irradiates the back of the transparent substrate and passes through the trenches. The photolithography light leaving the transmission face carries the pattern of the trenches. During this irradiation, charged particles can build up on the ends of the columns of absorption material. The ESD protection layer prevents electrostatic discharge from the ends of the columns.

Prevention of electrostatic discharge at the transmission face of the reticle helps to ensure that photolithography processes properly pattern the wafers. ESD events during a photolithography process can result in distortion of the pattern of the photolithography light. ESD events can also damage the reticle itself. The ESD protection layer helps ensure that such distortions and reticle damage do not happen. This results in better functioning integrated circuits and fewer scrapped wafers. Furthermore, this prevents destruction of reticles and corresponding expensive delays in performing photolithography processes when a damaged reticle needs to be replaced or repaired.

Embodiments of the present disclosure also enable effective repair of damaged reticles. During use of a photolithography reticle, sometimes there is a buildup of the absorption material on the bottoms of the trenches. An e-beam lithography tool is utilized to clear off unwanted absorption material from the bottoms of the trenches. The ESD protection layer is resistant to damage from the electron-beam. The ESD protection layer helps ensure that the columns of absorption material are not damaged by the e-beam lithography tool during repair of the reticle.

In some embodiments, a method includes forming an absorption layer on a substrate of a photolithography reticle. The substrate is transparent to photolithography light and the absorption layer absorbs the photolithography light. The method includes forming an electrostatic discharge (ESD) protection layer of a dielectric material on the absorption layer and exposing a top surface of the substrate by forming trenches in the absorption layer and the ESD protection layer.

In some embodiments, a method includes loading a photolithography reticle in an e-beam lithography tool and outputting an electron beam from the e-beam lithography tool into a trench in an absorption structure on a substrate of the photolithography reticle. The substrate is transparent to photolithography light. The method includes removing an opaque material from a surface of the substrate in the trench with the electron beam and shielding the absorption structure from the electron beam with a dielectric protection layer on the absorption structure.

In some embodiments, a photolithography reticle includes a substrate including a back surface and a front surface, wherein the substrate is transparent to photolithography light. The reticle includes an absorption structure on the front surface including an absorption layer having a material that is opaque to the photolithography light. The reticle includes a trench in the absorption structure exposing the front surface of the substrate and a dielectric protection layer on a top surface of the absorption structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an absorption layer on a substrate of a photolithography reticle, wherein the substrate is transparent to photolithography light and the absorption layer absorbs the photolithography light;
forming an electrostatic discharge (ESD) protection layer of a dielectric material on the absorption layer; and
exposing a top surface of the substrate by forming trenches in the absorption layer and the ESD protection layer.

2. The method of claim 1, further comprising:
forming an antireflection layer on the absorption layer;
forming the ESD protection layer on the antireflection layer; and
forming the trenches through the antireflection layer.

3. The method of claim 2, wherein a sheet resistance of the ESD protection layer is at least 1000 greater than a sheet resistance of the antireflection layer.

4. The method of claim 2, wherein the ESD protection layer is a top layer of the reticle after forming the trenches.

5. The method of claim 1, wherein the absorption layer and the antireflection layer both include molybdenum and silicon.

6. The method of claim 1, further comprising:
forming a chromium hard mask layer on the ESD protection layer;
patterning the chromium hard mask layer;
forming the trenches by performing an etching process in a presence of the chromium hard mask layer; and
removing the chromium hard mask layer after forming the trenches.

7. The method of claim 1, wherein the ESD protection layer includes one or more of silicon oxynitride, silicon nitride, zirconium oxide, aluminum oxide, yttrium oxide, and titanium oxide.

8. The method of claim 1, wherein the photolithography reticle is a super binary intensity mask.

9. The method of claim 1, wherein the ESD protection layer is less than or equal to 10 nm.

10. The method of claim 1, wherein the photolithography light has a wavelength of about 193 nm.

11. A method, comprising:
loading a photolithography reticle in an e-beam lithography tool;
outputting an electron beam from the e-beam lithography tool into a trench in an absorption structure on a substrate of the photolithography reticle, wherein the substrate is transparent to photolithography light;
removing an opaque material from a surface of the substrate in the trench with the electron beam; and
shielding the absorption structure from the electron beam with a dielectric protection layer on the absorption structure.

12. The method of claim 11, wherein removing the opaque material includes flowing a reaction gas onto the photolithography reticle.

13. The method of claim 11, wherein the absorption structure and the opaque material include molybdenum and silicon.

14. The method of claim 11, wherein the electron beam has a conical profile.

15. The method of claim 11, wherein the dielectric protection layer includes one or more of silicon oxynitride, silicon nitride, zirconium oxide, aluminum oxide, yttrium oxide, and titanium oxide.

16. The method of claim 11, further comprising repairing the reticle by removing the opaque material.

17. A photolithography reticle, comprising:
a substrate including a back surface and a front surface, wherein the substrate is transparent to photolithography light;
an absorption structure on the front surface including an absorption layer having a material that is opaque to the photolithography light;
a trench in the absorption structure exposing the front surface of the substrate; and
a dielectric protection layer on a top surface of the absorption structure.

18. The photolithography reticle of claim 17, wherein the absorption layer includes molybdenum and silicon, wherein the dielectric protection layer includes one or more of silicon oxynitride, silicon nitride, zirconium oxide, aluminum oxide, yttrium oxide, and titanium oxide.

19. The photolithography reticle of claim 17, wherein the absorption structure includes an antireflection layer on the absorption layer, wherein the dielectric protection layer is on the antireflection layer.

20. The photolithography reticle of claim 19, wherein a sheet resistance of the dielectric protection layer is at least 1000 greater than a sheet resistance of the antireflection layer.
